(19) United States
(12) Patent Application Publication
(10) Pub. No.: US 2024/0334665 A1
(43) Pub. Date: Oct. 3, 2024

(54) SUBSTRATE AND DISPLAY PANEL

(71) Applicant: TCL CHINA STAR OPTOELECTRONICS TECHNOLOGY CO., LTD., Shenzhen, Guangdong (CN)

(72) Inventor: Daobing HU, Shenzhen, Guangdong (CN)

(21) Appl. No.: 17/435,045

(22) PCT Filed: Aug. 11, 2021
(86) PCT No.: PCT/CN2021/111942

§ 371 Date: Jun. 13, 2024

(30) Foreign Application Priority Data
Aug. 3, 2021 (CN) 202110884638.6

(51) Int. Cl. H05K 9/00; H01L 27/12

(52) U.S. Cl. CPC H05K 9/0067; H01L 27/124

(57) ABSTRACT

Embodiment of the present application discloses a substrate and a display panel. In the substrate, a first electrostatic protection structure is correspondingly disposed in a peripheral area, a signal line is connected to the first electrostatic protection structure; a first common line is correspondingly disposed in the peripheral area, the first electrostatic protection structure is connected to the first common line; and a second common line is correspondingly disposed in the peripheral area, and is located on a side of the first common line away from a pixel arrangement area.

### FIELD OF INVENTION

The present application relates to a field of display technologies, in particular to a substrate and a display panel.

### BACKGROUND OF INVENTION

In research and practice of existing art, an inventor of the present application found that external charges easily enter internal traces in a backplane of a display panel. The backplane has many intersecting traces, and the external charges can easily cause electrostatic damage to overlapping traces.

### SUMMARY

### Technical Problem

Embodiments of the present application provide a substrate and a display panel, which can reduce a risk of damage to internal traces of the substrate by external charges.

### Technical Solutions for Problem

### Technical Solutions

An embodiment of the present application provides a substrate including a pixel arrangement area and a peripheral area arranged outside the pixel arrangement area; wherein the substrate further includes:
a signal line correspondingly disposed in the pixel arrangement area;
a first electrostatic protection structure correspondingly disposed in the peripheral area, wherein the signal line is connected to the first electrostatic protection structure;
a first common line correspondingly disposed in the peripheral area, wherein the first electrostatic protection structure is connected to the first common line; and
a second common line correspondingly disposed in the peripheral area and located on a side of the first common line away from the pixel arrangement area.

Optionally, in some embodiments of the present application, the substrate further includes a second electrostatic protection structure, one end of the second electrostatic protection structure is connected to the first common line, and another end of the second electrostatic protection structure is connected to the second common line.

Optionally, in some embodiments of the present application, the second common line includes a first line body and a second line body, the first line body and the second line body are disposed in different layers, and the first line body is electrically connected to the second line body.

Optionally, in some embodiments of the present application, the first line body is provided with a plurality of first openings, the second line body is provided with a plurality of second openings, and one of the first openings corresponds to one of the second openings.

Optionally, in some embodiments of the present application, the substrate includes a base and an insulating layer; the first line body is disposed on the base, the insulating layer is disposed on the first line body, and the second line body is disposed on the insulating layer; and
wherein the first line body and the second line body overlap each other; the insulating layer is provided with a plurality of via holes, and the first line body is connected to the second line body through the plurality of via holes.

Optionally, in some embodiments of the present application, the second electrostatic protection structure includes at least one electrostatic ring, the electrostatic ring includes a first thin film transistor and a second thin film transistor connected to each other, the first thin film transistor is connected to the first common line, and the second thin film transistor is connected to the second common line or another electrostatic ring.

Optionally, in some embodiments of the present application, a gate of the first thin film transistor is connected to a drain of the first thin film transistor, and the drain of the first thin film transistor is electrically connected to the first common line; a gate of the second thin film transistor is connected to a source of the second thin film transistor and a source of the first thin film transistor, and a drain of the second thin film transistor is connected to the second common line or the another electrostatic ring.

Optionally, in some embodiments of the present application, the second electrostatic protection structure includes at least two electrostatic rings, and adjacent ones of the electrostatic rings are arranged in series.

Optionally, in some embodiments of the present application, an arrangement direction of the electrostatic rings is parallel to an extension direction of the second common line.

Optionally, in some embodiments of the present application, the substrate further includes an active layer, a source, and a drain, the active layer is disposed on the insulating layer, the source and the drain are disposed in a same layer as the second line body, the source and the drain are connected to the active layer, and the second line body is connected to the drain of the second thin film transistor.

Optionally, in some embodiments of the present application, the first common line includes a first trace and a second trace, the first trace and the first line body are disposed in a same layer, the second trace and the second line body are disposed in a same layer, and the first trace is electrically connected to the second trace; and
wherein the substrate further includes a gate, the gate and the first trace are disposed in a same layer, and a gate of the first thin film transistor is connected to the first trace.

Optionally, in some embodiments of the present application, the substrate further includes a third common line correspondingly disposed in the peripheral area and located on a side of the first common line close to the pixel arrangement area; and
wherein the signal line includes a first signal line and a second signal line, the first signal line is connected to the third common line through the first electrostatic protection structure, and the second signal line is connected to the first common line through the first electrostatic protection structure.

Optionally, in some embodiments of the present application, the first electrostatic protection structure connected to the third common line includes at least two electrostatic rings connected in series.

Optionally, in some embodiments of the present application, the first signal line includes a scan line and a data line, and the second signal line includes a first power line and a second power line.

Another embodiment of the present application also relates to a display panel, which includes pixels and a substrate, the substrate including a pixel arrangement area and a peripheral area arranged outside the pixel arrangement area; wherein the substrate includes:
a signal line correspondingly disposed in the pixel arrangement area;
a first electrostatic protection structure correspondingly disposed in the peripheral area, wherein the signal line is connected to the first electrostatic protection structure;
a first common line correspondingly disposed in the peripheral area, wherein the first electrostatic protection structure is connected to the first common line; and
a second common line correspondingly disposed in the peripheral area and located on a side of the first common line away from the pixel arrangement area.

Optionally, in some embodiments of the present application, the substrate further includes a second electrostatic protection structure, one end of the second electrostatic protection structure is connected to the first common line, and another end of the second electrostatic protection structure is connected to the second common line.

Optionally, in some embodiments of the present application, the second common line includes a first line body and a second line body, the first line body and the second line body are disposed in different layers, and the first line body is electrically connected to the second line body.

Optionally, in some embodiments of the present application, the first line body is provided with a plurality of first openings, the second line body is provided with a plurality of second openings, and one of the first openings corresponds to one of the second openings.

Optionally, in some embodiments of the present application, the substrate includes a base and an insulating layer; the first line body is disposed on the base, the insulating layer is disposed on the first line body, and the second line body is disposed on the insulating layer; and
wherein the first line body and the second line body overlap each other; the insulating layer is provided with a plurality of via holes, and the first line body is connected to the second line body through the plurality of via holes.

Optionally, in some embodiments of the present application, the second electrostatic protection structure includes at least one electrostatic ring, the electrostatic ring includes a first thin film transistor and a second thin film transistor connected to each other, the first thin film transistor is connected to the first common line, and the second thin film transistor is connected to the second common line or another electrostatic ring.

Optionally, in some embodiments of the present application, a gate of the first thin film transistor is connected to a drain of the first thin film transistor, and the drain of the first thin film transistor is electrically connected to the first common line; a gate of the second thin film transistor is connected to a source of the second thin film transistor and a source of the first thin film transistor, and a drain of the second thin film transistor is connected to the second common line or the another electrostatic ring.

Optionally, in some embodiments of the present application, the second electrostatic protection structure includes at least two electrostatic rings, and adjacent ones of the electrostatic rings are arranged in series.

Optionally, in some embodiments of the present application, an arrangement direction of the electrostatic rings is parallel to an extension direction of the second common line.

Optionally, in some embodiments of the present application, the substrate further includes an active layer, a source, and a drain, the active layer is disposed on the insulating layer, the source and the drain are disposed in a same layer as the second line body, the source and the drain are connected to the active layer, and the second line body is connected to the drain of the second thin film transistor.

Optionally, in some embodiments of the present application, the first common line includes a first trace and a second trace, the first trace and the first line body are disposed in a same layer, the second trace and the second line body are disposed in a same layer, and the first trace is electrically connected to the second trace; and
wherein the substrate further includes a gate, the gate and the first trace are disposed in a same layer, and a gate of the first thin film transistor is connected to the first trace.

Optionally, in some embodiments of the present application, the substrate further includes a third common line correspondingly disposed in the peripheral area and located on a side of the first common line close to the pixel arrangement area; and
wherein the signal line includes a first signal line and a second signal line, the first signal line is connected to the third common line through the first electrostatic protection structure, and the second signal line is connected to the first common line through the first electrostatic protection structure.

Optionally, in some embodiments of the present application, the first electrostatic protection structure connected to the third common line includes at least two electrostatic rings connected in series.

Optionally, in some embodiments of the present application, the first signal line includes a scan line and a data line, and the second signal line includes a first power line and a second power line.

### Beneficial Effect of the Invention

### Beneficial Effect

In the substrate and the display panel provided by embodiments of the present application, a first electrostatic protection structure is correspondingly arranged in a peripheral area, a signal line is connected to the first electrostatic protection structure, a first common line is correspondingly disposed in the peripheral area, and the first electrostatic protection structure is connected to the first common line, and a second common line is correspondingly disposed in the peripheral area and located on a side of the first common line away from a pixel arrangement area. In the embodiment of the present application, a second common line is added in the peripheral area. When external charges contact the second common line, part of the charges is conducted to a ground terminal by the second common line, thereby reducing a risk of damage to the internal traces of a substrate by the external charges.

### ILLUSTRATION OF THE DRAWINGS

### Brief Description of the Drawings

In order to more clearly illustrate the technical solutions of the embodiments of the present application, the drawings illustrating the embodiments will be briefly described below. Obviously, the drawings in the following description merely illustrate some embodiments of the present invention. Other drawings may also be obtained by those skilled in the art according to these figures without paying creative work.

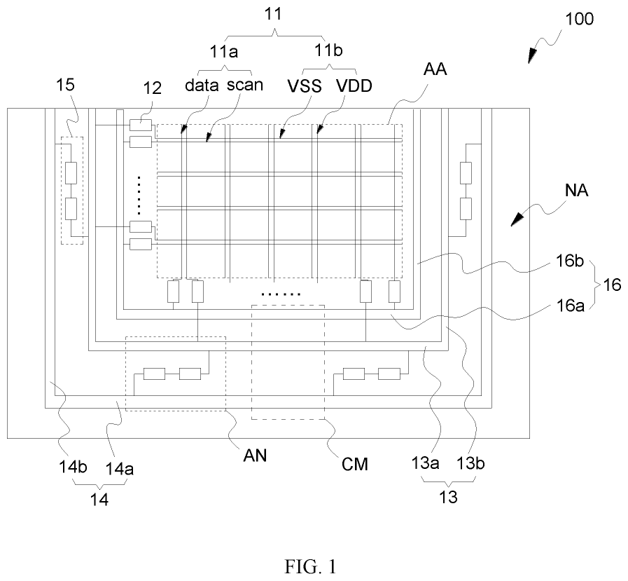

FIG. 1 is a schematic structural diagram of a substrate provided by an embodiment of the present application.

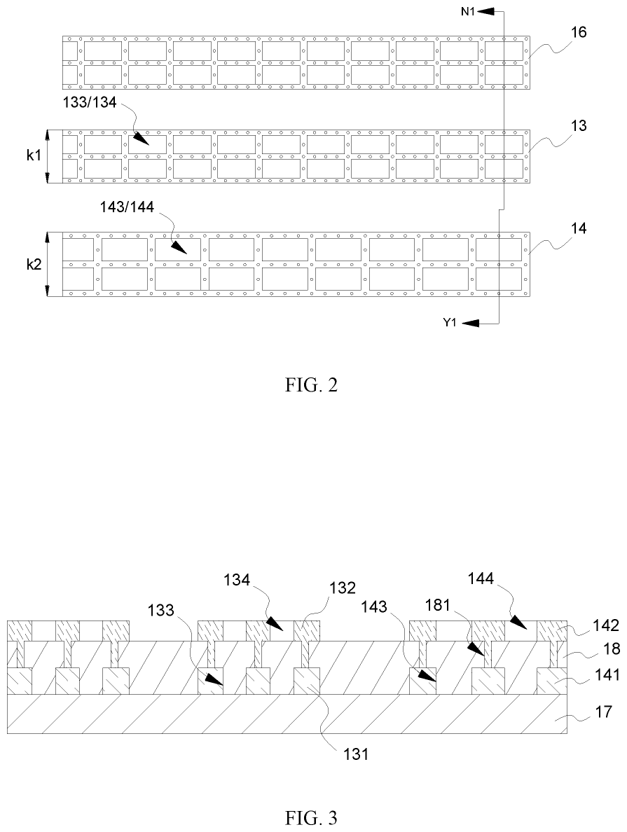

FIG. 2 is an enlarged schematic diagram of a portion CM in FIG. 1.

FIG. 3 is a schematic sectional view of a structure taken along line N1T1 in FIG. 2.

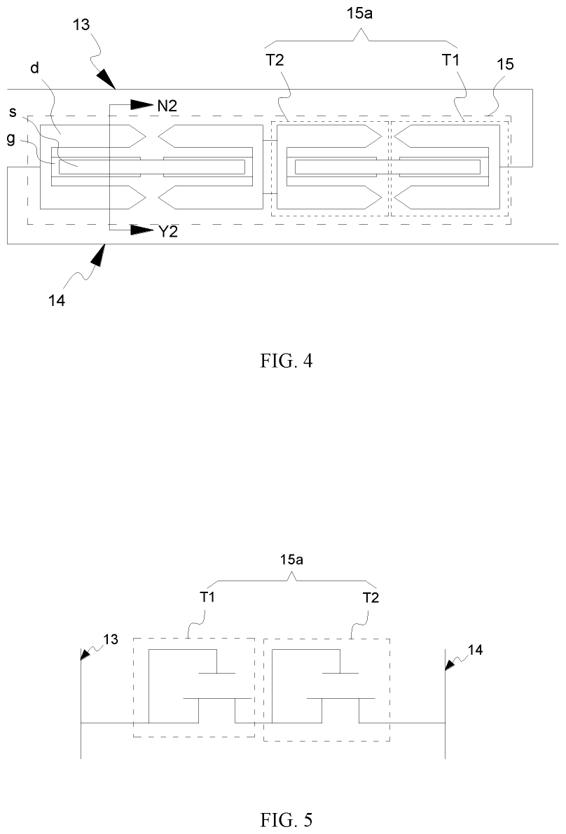

FIG. 4 is an enlarged schematic diagram of a portion AN in FIG. 1.

FIG. 5 is an equivalent circuit diagram of a second electrostatic protection structure in the substrate provided by an embodiment of the present application.

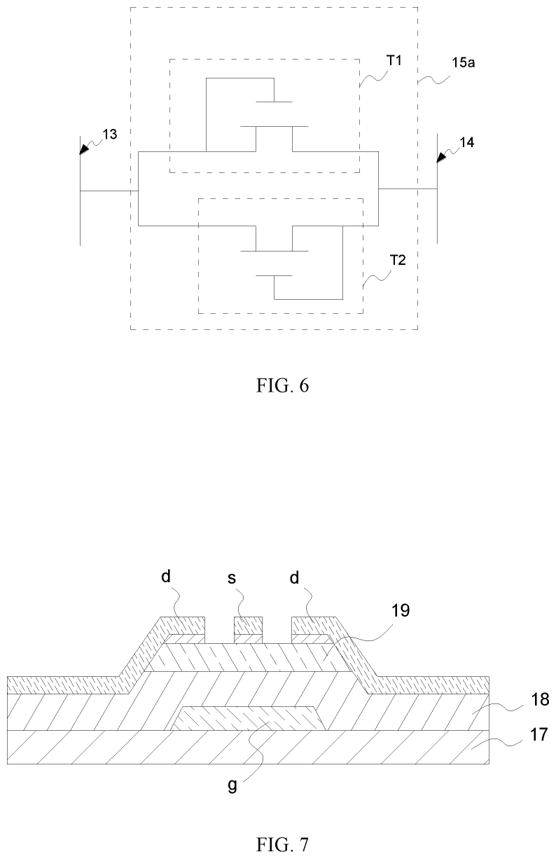

FIG. 6 is another equivalent circuit diagram of the second electrostatic protection structure in the substrate provided by an embodiment of the present application.

FIG. 7 is a schematic sectional view of a structure taken along line N2T2 in FIG. 4.

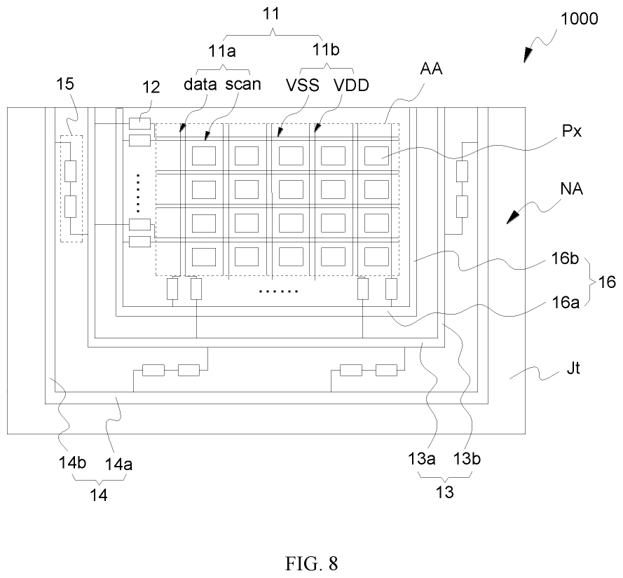

FIG. 8 is a schematic structural diagram of a display panel provided by an embodiment of the present application.

### IMPLEMENTATIONS OF THE INVENTION

### Detailed Description of Embodiments

In addition, it should be understood that the specific implementations described here are only used to illustrate and explain the present application, and are not used to limit the present application. In the present application, unless otherwise stated, the orientation words used such as “upper” and “lower” generally refer to the upper and lower directions of the device in actual use or working state, and specifically refer to the drawing directions in the drawings, while “inner” and “outer” refer to the outline of the device.

Embodiments of the present application provide a substrate and a display panel, which will be described in detail below. It should be noted that the order of description in the following embodiments is not intended to limit the preferred order of the embodiments.

Referring to FIG. 1, an embodiment of the present application provides a substrate 100 that includes a pixel arrangement area AA and a peripheral area NA, and the peripheral area NA is arranged outside the pixel arrangement area AA. The substrate 100 includes a signal line 11, a first electrostatic protection structure 12, a first common line 13, and a second common line 14.

The signal line 11 is correspondingly disposed in the pixel arrangement area AA.

The first electrostatic protection structure 12 is correspondingly disposed in the peripheral area NA. The signal line 11 is connected to the first electrostatic protection structure 12. The first common line 13 is correspondingly disposed in the peripheral area NA. The first static protection structure 12 is connected to the first common line 13.

The second common line 14 is correspondingly disposed in the peripheral area NA, and located on a side of the first common line 13 away from the pixel arrangement area AA.

The substrate 100 of an embodiment of the present application is additionally provided with the second common line 14 in the peripheral area NA. When external charges contact the second common line 14, part of the charges is conducted to a ground terminal by the second common line 14.

The substrate 100 further includes a second electrostatic protection structure 15. One end of the second electrostatic protection structure 15 is connected to the first common line 13, and another end of the second electrostatic protection structure 15 is connected to the second common line 14.

The second electrostatic protection structure 15 is provided between the second common line 14 and the first common line 13, and the second electrostatic protection structure 15 is used to block charges conducted to the second common line from entering the pixel arrangement area AA, thereby reducing a risk of the external charges entering the pixel arrangement area AA, thus further reducing a risk of damage to internal traces of the substrate 100 by the external charges.

That is, the first common line 13 and the second common line 14 are used to conduct the external charges away and prevent the external charges from entering the substrate 100. Optionally, the first common line 13 and the second common line 14 are ground lines.

Optionally, the signal line 11 includes a scan line “scan”, a data line “data”, a first power line “VDD”, and a second power line “VSS”. In this embodiment, at least one of above four signal lines 11 may be connected to the first common line 13.

Optionally, referring to FIG. 1, the substrate 100 may further include a third common line 16. The third common line 16 is correspondingly disposed in the peripheral area NA, and located on a side of the first common line 13 close to the pixel arrangement area AA.

The signal line 11 includes a first signal line 11a and a second signal line 11b. The first signal line 11a is connected to the third common line 16 through the first electrostatic protection structure 12. The second signal line 11b is connected to the first common line 13 through the first electrostatic protection structure 12.

Optionally, the first electrostatic protection structure 12 connected to the third common line 16 includes at least two electrostatic rings connected in series.

Of course, in some embodiments, the first electrostatic protection structure 12 connected to the third common line 16 and the first electrostatic protection structure 12 connected to the first common line 13 may be the same or different. For example, the first electrostatic protection structure 12 connected to the first common line 13 includes an electrostatic ring; and the first electrostatic protection structure 12 connected to the third common line 16 includes two electrostatic rings arranged in series.

A structure of the electrostatic ring of the first electrostatic protection structure 12 is similar to or the same as a structure of a electrostatic ring 15a of the second electrostatic protection structure 15. The detailed description will be provided below, and will not be repeated here.

Optionally, the first signal line 11a includes the scan line “scan” and the data line “data”. The second signal line 11b includes the first power line “VDD” and the second power line “VSS”.

In the present application, the first signal line 11a is correspondingly connected to the third common line 16, and the second signal line 11b is correspondingly connected to the first common line 13. Since the third common line 16 is located on the side of the first common line 13 close to the pixel arrangement area AA, compared with the first common line 13 and the second common line 14, the third common line 16 has a lowest risk of being introduced with the external charges, making the first signal line 11a relatively safer.

In addition, by connecting the first signal line 11a correspondingly to the third common line 16 and connecting the second signal line 11b correspondingly to the first common line 13, a risk of the first signal line 11a and the second signal line 11b being damaged together is reduced.

Optionally, a width k2 of the second common line 14 is greater than a width k3 of the third common line 16.

Referring to FIG. 1, optionally, the first common line 13 includes a first section 13a and a second section 13b. One end of the first section 13a is connected to the second section 13b, and another end of the first section 13a is connected to another second section 13b. An extension direction of the first section 13a is parallel to an extension direction of the scan line “scan”, and an extension direction of the second section 13b is parallel to an extension direction of the data line “data”.

The extension direction of the first section 13a intersects the extension direction of the second section 13b. A width of the first section 13a is greater than a width of the second section 13b.

Optionally, the second common line 14 includes a third section 14a and a fourth section 14b. One end of the third section 14a is connected to a fourth section 14b, and another end of the third section 14a is connected to another fourth section 14b. An extension direction of the third section 14a is parallel to the extension direction of the first section 13a, and an extension direction of the fourth section 14b is parallel to the extension direction of the second section 13b.

A width of the third section 14a is greater than a width of the fourth section 14b.

Optionally, the third common line 16 includes a fifth section 16a and a sixth section 16b. One end of the fifth section 16a is connected to a sixth section 16b, and another end of the fifth section 16a is connected to another sixth section 16b. An extension direction of the fifth section 16a is parallel to the extension direction of the first section 13a, and an extension direction of the sixth section 16b is parallel to the extension direction of the second section 13b.

A width of the fifth section 16a is greater than a width of the sixth section 16b.

Optionally, the width of the first section 13a is greater than or equal to the width of the third section 14a. The width of the first section 13a is greater than or equal to the width of the fifth section 16a. Such an arrangement can reasonably arrange a space of a lower part of the peripheral area NA to achieve an effect of reducing a lower frame.

Optionally, the width of the first section 13a may be 100 micrometers, 110 micrometers, 120 micrometers, or the like. Each of the width of the third section 14a and the width of the fifth section 16a may be 100 micrometers, 110 micrometers, 120 micrometers, or the like.

Optionally, the width of the second section 13b is greater than the width of the fourth section 14b and the width of the sixth section 16b. Such an arrangement can reasonably arrange a space of the left and right parts of the peripheral area NA to achieve an effect of reducing left and right frames.

Optionally, the width of the second section 13b may be 90 micrometers, 100 micrometers, 110 micrometers, or the like. Each of the width of the fourth section 14b and the width of the sixth section 16b may be 80 micrometers, 90 micrometers, 100 micrometers, or the like.

Optionally, a distance between the first common line 13 and the second common line 14 is greater than a distance between the first common line 13 and the third common line 16, so as to reasonably use the space of the peripheral area NA to achieve an effect of reducing the frames.

Optionally, the scan line “scan” is correspondingly connected to the sixth section 16b. The data line “data” is correspondingly connected to the fifth section 16a. The first power line “VDD” is correspondingly connected to the first section 13a. The second power line “VSS” is correspondingly connected to the first section 13a or the second section 13b.

Referring to FIGS. 2 and 3, optionally, the second common line 14 includes a first line body 141 and a second line body 142, and the first line body 141 and the second line body 142 are arranged in different layers. The first line body 141 is electrically connected to the second line body 142.

The second common line 14 of the substrate 100 in this embodiment adopts a double-layered trace arrangement, which increases area of the second common line 14 so as to accommodate more static electricity and enhance protection against the static electricity.

Optionally, a plurality of first openings 143 are defined on the first line body 141, and a plurality of second openings 144 are defined on the second line body 142. One of the first openings 143 corresponds to one of the second openings 144.

In this embodiment, the first opening 143 and the second opening 144 are respectively defined on the first line body 141 and the second line body 142 to increase resistance of the second common line 14.

Optionally, the substrate 100 includes a base 17 and an insulating layer 18. The first line body 141 is provided on the base 17. The insulating layer 18 is provided on the first line body 141. The second line body 142 is provided on the insulating layer 18.

The first line body 141 overlaps the second line body 142. The insulating layer 18 is configured with a plurality of via holes 181. The first line body 141 is connected to the second line body 142 through the plurality of via holes 181.

In this embodiment, the first line body 141 is connected to the second line body 142 through the plurality of via holes 181. When the static electricity enters one of the first line body 141 and the second line body 142, the static electricity can be quickly discharged to another one of the first line body 141 and the second line body 142 to improve discharge efficiency of the static electricity.

In some embodiments, the first line body 141 may also be connected to the second line body 142 through only one via hole 181.

Optionally, the first common line 13 may have a single-layered structure or a double-layered trace structure. In this embodiment, the first common line 13 having the double-layered trace structure is described for illustrative purpose, but it is not particularly limited thereto.

The first common line 13 includes a first trace 131 and a second trace 132, and the first trace 131 and the second trace 132 are arranged in different layers. The first trace 131 is electrically connected to the second trace 132.

The second common line 14 of the substrate 100 in this embodiment adopts the double-layered trace arrangement, which increases the area of the second common line 13 so as to accommodate more static electricity and enhance the protection against the static electricity.

Optionally, a plurality of third openings 133 are defined on the first trace 131. A plurality of fourth openings 134 are defined on the second trace 132. One of the third openings 133 corresponds to one of the fourth openings 134.

In this embodiment, the first trace 131 and the second trace 132 are respectively configured with the third opening 133 and the fourth opening 134 to increase resistance of the first common line 13.

Optionally, the first trace 131 and the first line body 141 are disposed in a same layer; and the second trace 132 and the second line body 142 are disposed in a same layer.

The first trace 131 overlaps the second trace 132. A plurality of via holes 181 are defined on the insulating layer 18. The first trace 131 is connected to the second trace 132 through the plurality of via holes 181.

In this embodiment, the first trace 131 is connected to the second trace 132 through the plurality of via holes 181. When the static electricity enters one of the first trace 1311 and the second trace 132, the static electricity can be quickly discharged to another one of the first trace 131 and the second trace 132 to improve the discharge efficiency of the static electricity.

Optionally, a material of each of the first trace 131 and the first line body 141 may be metal, such as copper, aluminum, titanium, or alloy. A material of each of the second trace 132 and the second line body 142 may also be metal, such as copper, aluminum, titanium, or alloys.

Optionally, the width k2 of the second common line 14 is larger than the width k1 of the first common line 13, so as to increase electrostatic dissipation capacity of the second common line 14 which is located further outside, thereby further reducing a risk of the static electricity entering the pixel arrangement area AA.

Optionally, a structure of the third common line 16 is similar to or the same as a structure of the first common line 13.

Referring to FIGS. 4 and 5, optionally, the second electrostatic protection structure 15 includes at least one electrostatic ring 15a, and the electrostatic ring 15a includes a first thin film transistor T1 and a second thin film transistor T2. The first thin film transistor T1 is connected to the first common line 13, and the second thin film transistor T2 is connected to the second common line 14 or another electrostatic ring 15a.

That is, when the second electrostatic protection structure 15 includes one electrostatic ring 15a, the second thin film transistor T2 is connected to the second common line 14; and when the second electrostatic protection structure 15 includes at least two electrostatic rings 15a, the second thin film transistor T2 in one of the electrostatic rings 15a is connected to a next electrostatic ring 15a.

Optionally, referring to FIGS. 1 and 4, the second electrostatic protection structure 15 includes at least two electrostatic rings 15a, and adjacent ones of the electrostatic rings 15a are arranged in series. In the present application, the series arrangement of the electrostatic rings 15a is adopted to increase electrostatic protection capability of the second electrostatic protection structure 15.

The substrate 100 of this embodiment is described by taking two electrostatic rings 15a arranged in series as an example, but it is not particularly limited thereto.

Optionally, an arrangement direction of the electrostatic rings 15a is parallel to an extension direction of the second common line 14. Such an arrangement saves a longitudinal arrangement space of the electrostatic layer 15a.

Optionally, referring to FIG. 5, a gate of the first thin film transistor T1 is connected to a drain of the first thin film transistor T1. The drain of the first thin film transistor T1 is electrically connected to the first common line 13. A gate of the second thin film transistor T2 is connected to a source of the second thin film transistor T2 and a source of the first thin film transistor T1. A drain of the second thin film transistor T2 is connected to the second common line 14 or another electrostatic ring 15a.

Optionally, referring to FIG. 6, a structure of the electrostatic ring 15a may also be: the gate of the first thin film transistor T1 is connected to the drain of the first thin film transistor T1, the source of the first thin film transistor T1 is connected to the drain of the second thin film transistor T2, the drain of the second thin film transistor T2 is connected to the gate of the second thin film transistor T2, and the source of the second thin film transistor T2 is connected to the drain of the first thin film transistor T1. The first common line 13 is connected to the drain of the first thin film transistor T1, and the second common line 14 is connected to the drain of the second thin film transistor T2.

It should be noted that the source and the drain of the thin film transistor are symmetrical, so the source and the drain are interchangeable. In the embodiments of the present application, in order to distinguish two electrodes of the thin film transistor other than the gate, one of the electrodes is called the source and the other is called the drain.

Optionally, a structure of the first electrostatic protection structure 12 is similar to or the same as a structure of the second electrostatic protection structure 15. Therefore, descriptions of the first electrostatic protection structure 12 can be referred to details of the second electrostatic protection structure 15, which will not be repeated herein for brevity.

Referring to FIG. 7, optionally, the substrate 100 further includes an active layer 19, a source s, and a drain d. The active layer 19 is arranged on the insulating layer 18, and the source s, the drain d, and the second line body 142 are disposed in a same layer. The source s and the drain d are connected to the active layer 19. The second line body 142 is connected to the drain d of the second thin film transistor T2.

Optionally, the substrate 100 further includes a gate g, and the gate g and the first trace 131 are disposed in a same layer. The gate g of the first thin film transistor T1 is connected to the first trace 131.

In the present application, the second line body 142 is connected to the drain d of the second thin film transistor T2, and the gate g of the first thin film transistor T1 is connected to the first trace 131. That is, the electrical connection is integrally formed in a same layer to prevent connections through via holes, thereby simplifying the process.

Optionally, the substrate 100 can be used as a backplane of a micro-LED panel or a sub-millimeter light-emitting diode (mini-LED) panel, and the pixel arrangement area AA is used for disposing light-emitting diode devices.

Optionally, the substrate 100 may also be used as a backplane of an electroluminescent panel. The electroluminescent panel may be an organic light-emitting diode panel (OLED) or a quantum dot light-emitting diode panel (QLED), and the pixel arrangement area AA is used for disposing light-emitting diodes.

Optionally, the substrate 100 may also be used as an array substrate of a liquid crystal display panel (LCD), and the pixel arrangement area AA is used for disposing pixel electrodes.

Referring to FIG. 8, an embodiment of the present application also relates to a display panel 1000, which includes pixels Px and a substrate Jt. The pixels Px are correspondingly arranged in the pixel arrangement area AA.

It should be noted that a structure of the substrate Jt of the display panel 1000 in this embodiment is similar to or the same as the structure of the substrate 100 of foregoing embodiment, and details can be referred to the description of the substrate 100 of the foregoing embodiment, which will not be repeated herein for brevity.

Optionally, the display panel 1000 is a liquid crystal display panel, and the pixels Px include pixel electrodes.

Optionally, in another embodiment, the display panel 1000 may be an electroluminescence panel. The electroluminescence panel may be an organic light-emitting diode panel (OLED) or a quantum dot light-emitting diode panel (QLED), and the pixels Px include light-emitting diodes.

Optionally, in still another embodiment, the display panel 1000 may be a micro-LED panel or a sub-millimeter light-emitting diode (mini-LED) panel, and the pixels Px include light-emitting diode devices.

In the substrate and the display panel provided by embodiments of the present application, a first electrostatic protection structure is correspondingly arranged in a peripheral area, a signal line is connected to the first electrostatic protection structure, a first common line is correspondingly disposed in the peripheral area, and the first electrostatic protection structure is connected to the first common line, and a second common line is correspondingly disposed in the peripheral area and located on a side of the first common line away from a pixel arrangement area. In this embodiment of the present application, the second common line is added in the peripheral area, and the second electrostatic protection structure is disposed between the second common line and the first common line, so that, after external charges contact the second common line, part of charges is conducted to a ground terminal by the second common line, and part of the charges is blocked by the second electrostatic protection structure, so as to reduce a risk of the external charges entering the pixel arrangement area, thereby reducing a risk of damage to internal traces of the substrate by the external charges.

The substrate and the display panel disposed in the embodiments of the present application have been described in detail above. Specific examples are used in this document to explain the principles and implementation of the present invention. The descriptions of the above embodiments are only for understanding the method of the present invention and its core ideas, to help understand the technical solution of the present application and its core ideas, and a person of ordinary skill in the art should understand that it can still modify the technical solution described in the foregoing embodiments, or equivalently replace some of the technical features. Such modifications or replacements do not depart the spirit of the corresponding technical solutions beyond the scope of the technical solutions of the embodiments of the present application.

What is claimed is:

1. A substrate, comprising a pixel arrangement area and a peripheral area arranged outside the pixel arrangement area; wherein the substrate further comprises:
a signal line correspondingly disposed in the pixel arrangement area;
a first electrostatic protection structure correspondingly disposed in the peripheral area, wherein the signal line is connected to the first electrostatic protection structure;
a first common line correspondingly disposed in the peripheral area, wherein the first electrostatic protection structure is connected to the first common line; and
a second common line correspondingly disposed in the peripheral area and located on a side of the first common line away from the pixel arrangement area.

2. The substrate according to claim 1, wherein the substrate further comprises a second electrostatic protection structure, one end of the second electrostatic protection structure is connected to the first common line, and another end of the second electrostatic protection structure is connected to the second common line.

3. The substrate according to claim 2, wherein the second common line comprises a first line body and a second line body, the first line body and the second line body are disposed in different layers, and the first line body is electrically connected to the second line body.

4. The substrate according to claim 3, wherein the first line body is provided with a plurality of first openings, the second line body is provided with a plurality of second openings, and one of the first openings corresponds to one of the second openings.

5. The substrate according to claim 3, wherein the substrate comprises a base and an insulating layer; the first line body is disposed on the base, the insulating layer is disposed on the first line body, and the second line body is disposed on the insulating layer; and
wherein the first line body and the second line body overlap each other; the insulating layer is provided with a plurality of via holes, and the first line body is connected to the second line body through the plurality of via holes.

6. The substrate according to claim 5, wherein the second electrostatic protection structure comprises at least one electrostatic ring, the electrostatic ring comprises a first thin film transistor and a second thin film transistor connected to each other, the first thin film transistor is connected to the first common line, and the second thin film transistor is connected to the second common line or another electrostatic ring.

7. The substrate according to claim 6, wherein a gate of the first thin film transistor is connected to a drain of the first thin film transistor, and the drain of the first thin film transistor is electrically connected to the first common line; a gate of the second thin film transistor is connected to a source of the second thin film transistor and a source of the first thin film transistor, and a drain of the second thin film transistor is connected to the second common line or the another electrostatic ring.

8. The substrate according to claim 6, wherein the second electrostatic protection structure comprises at least two electrostatic rings, and adjacent ones of the electrostatic rings are arranged in series.

9. The substrate according to claim 8, wherein an arrangement direction of the electrostatic rings is parallel to an extension direction of the second common line.

10. The substrate according to claim 6, wherein the substrate further comprises an active layer, a source, and a drain, the active layer is disposed on the insulating layer, the source and the drain are disposed in a same layer as the second line body, the source and the drain are connected to the active layer, and the second line body is connected to a drain of the second thin film transistor.

11. The substrate according to claim 10, wherein the first common line comprises a first trace and a second trace, the first trace and the first line body are disposed in a same layer, the second trace and the second line body are disposed in a same layer, and the first trace is electrically connected to the second trace; and
wherein the substrate further includes a gate, the gate and the first trace are disposed in a same layer, and a gate of the first thin film transistor is connected to the first trace.

12. The substrate according to claim 1, wherein the substrate further comprises a third common line correspondingly disposed in the peripheral area and located on a side of the first common line close to the pixel arrangement area; and
wherein the signal line includes a first signal line and a second signal line, the first signal line is connected to the third common line through the first electrostatic protection structure, and the second signal line is connected to the first common line through the first electrostatic protection structure.

13. The substrate according to claim 12, wherein the first electrostatic protection structure connected to the third common line comprises at least two electrostatic rings connected in series.

14. The substrate according to claim 11, wherein a first signal line includes a scan line and a data line, and a second signal line includes a first power line and a second power line.

15. A display panel, comprising pixels and a substrate, the substrate comprising a pixel arrangement area and a peripheral area arranged outside the pixel arrangement area, and the pixels correspondingly disposed in the pixel arrangement area; wherein the substrate comprises:
a signal line correspondingly arranged in the pixel arrangement area;
a first electrostatic protection structure correspondingly disposed in the peripheral area, wherein the signal line is connected to the first electrostatic protection structure;
a first common line correspondingly disposed in the peripheral area, wherein the first electrostatic protection structure is connected to the first common line; and
a second common line correspondingly disposed in the peripheral area and located on a side of the first common line away from the pixel arrangement area.

16. The display panel according to claim 15, wherein the substrate further comprises a second electrostatic protection structure, one end of the second electrostatic protection structure is connected to the first common line, and another end of the second electrostatic protection structure is connected to the second common line.

17. The display panel according to claim 16, wherein the second common line comprises a first line body and a second line body, the first line body and the second line body are disposed in different layers, and the first line body is electrically connected to the second line body.

18. The display panel according to claim 17, wherein the first line body is provided with a plurality of first openings, the second line body is provided with a plurality of second openings, and one of the first openings corresponds to one of the second openings.

19. The display panel according to claim 18, wherein the substrate comprises a base and an insulating layer; the first line body is disposed on the base, the insulating layer is disposed on the first line body, and the second line body is disposed on the insulating layer; and
wherein the first line body and the second line body overlap each other; the insulating layer is provided with a plurality of via holes, and the first line body is connected to the second line body through the plurality of via holes.

20. The display panel according to claim 19, wherein the second electrostatic protection structure comprises at least one electrostatic ring, the electrostatic ring comprises a first thin film transistor and a second thin film transistor connected to each other, the first thin film transistor is connected to the first common line, and the second thin film transistor is connected to the second common line or another electrostatic ring.
